(19) United States
(12) Patent Application Publication
(10) Pub. No.: US 2025/0071943 A1
(43) Pub. Date: Feb. 27, 2025

(54) ACTIVE/PASSIVE COOLING SYSTEM WITH PUMPED REFRIGERANT

(71) Applicant: Munters Corporation, Amesbury, MA (US)

(72) Inventors: Wei Fang, San Antonio, TX (US); Rafael Neuwald, Lexington, VA (US); Michael Boucher, Lexington, VA (US)

(21) Appl. No.: 18/726,253

(22) PCT Filed: Jan. 6, 2023
(86) PCT No.: PCT/US2023/060192

§ 371 Date: Jul. 2, 2024

Related U.S. Application Data
(60) Provisional application No. 63/297,000, filed on Jan. 6, 2022.

(51) Int. Cl. H05K 7/20

(52) U.S. Cl. CPC H05K 7/20327; H05K 7/20309; H05K 7/20318; H05K 7/20827

(57) ABSTRACT

A cooling system including an evaporator, a passive condenser, a heat exchanger, and a pump. The passive condenser is arranged in parallel with the heat exchanger relative to the fluid flow of a primary cooling medium. When a secondary cooling medium is provided to the heat exchanger, at least some of a primary cooling medium in the gas phase switches from being received by the passive condenser to the heat exchanger without operating any valves and supplies the primary cooling medium in the liquid phase to the evaporator. When the secondary cooling medium is not provided to the heat exchanger, the heat exchanger does not supply the primary cooling medium in the liquid phase to the evaporator. The pump is located in a liquid line fluidly connecting the evaporator to the passive condenser and the heat exchanger and pumps the primary cooling medium in the liquid phase to the evaporator.

### FIELD OF THE INVENTION

This invention relates to cooling systems and systems and methods to control them. In particular, this invention relates to a cooling system having both active and passive modes. A particularly suitable application, for example, is in data center cooling systems.

### BACKGROUND OF THE INVENTION

Data centers often require large amounts of energy to operate. The servers in these data centers generate a large amount of heat, requiring cooling. To reduce the energy use of data centers, more efficient cooling systems are desired.

### SUMMARY OF THE INVENTION

In one aspect, the invention relates to a cooling system including an evaporator, a passive condenser, a heat exchanger, a liquid line, and a pump. The evaporator contains a primary cooling medium. The evaporator is configured to receive a process fluid and, when receiving the process fluid, extract heat from the process fluid to cool the process fluid and to change the phase of the primary cooling medium from liquid to gas. The passive condenser includes an outer surface and is fluidly coupled to the evaporator. The passive condenser is configured to have an airstream directed over the outer surface thereof, and when the airstream is directed over the outer surface of the passive condenser, the passive condenser is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator. The heat exchanger is fluidly coupled to the evaporator and configured to have a secondary cooling medium selectively provided thereto. When the secondary cooling medium is provided to the heat exchanger, at least some of the primary cooling medium in the gas phase switches from being received by the passive condenser to the heat exchanger without operating any valves located between the evaporator and the passive condenser and between the evaporator and the heat exchanger, and the heat exchanger is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator. When the secondary cooling medium is not provided to the heat exchanger, the heat exchanger does not supply the primary cooling medium in the liquid phase to the evaporator. The liquid line fluidly connects the evaporator to each of the passive condenser and the heat exchanger to supply the primary cooling medium in the liquid phase to the evaporator from at least one of the passive condenser and the heat exchanger. The pump is located in the liquid line and configured to pump the primary cooling medium in the liquid phase to the evaporator. The passive condenser is arranged in parallel with the heat exchanger relative to the fluid flow of the primary cooling medium.

In another aspect, the invention relates to a cooling system including an evaporator, a plurality of passive condensers, at least one heat exchanger, a liquid line, and a pump. The evaporator contains a primary cooling medium. The evaporator is configured to receive a process fluid and, when receiving the process fluid, extract heat from the process fluid to cool the process fluid and to change the phase of the primary cooling medium from liquid to gas. Each passive condenser has an outer surface and is fluidly coupled to the evaporator. Each passive condenser being configured to have an airstream directed over the outer surface thereof, and, when the airstream is directed over the outer surface of the passive condenser, the passive condenser is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator. The at least one heat exchanger is fluidly coupled to the evaporator and configured to have a secondary cooling medium selectively provided thereto. When the secondary cooling medium is provided to the at least one heat exchanger, at least some of the primary cooling medium in the gas phase switches from being received by the passive condenser to the at least one heat exchanger without operating any valves located between the evaporator and the passive condenser and between the evaporator, and the heat exchanger and the at least one heat exchanger is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator. When the secondary cooling medium is not provided to the at least one heat exchanger, the heat exchanger does not supply the primary cooling medium in the liquid phase to the evaporator. The liquid line fluidly connects the evaporator to each passive condenser of the plurality of passive condensers and the at least one heat exchanger to supply the primary cooling medium in the liquid phase to the evaporator from at least one of the plurality of passive condensers and the at least one heat exchanger. The pump located in the liquid line and configured to pump the primary cooling medium in the liquid phase to the evaporator. At least one passive condenser of the plurality of passive condensers is arranged in parallel with the at least one heat exchanger relative to the fluid flow of the primary cooling medium.

These and other aspects of the invention will become apparent from the following disclosure.

### BRIEF DESCRIPTION OF THE DRAWINGS

FIG. 1 is an elevation view of a multi-story data center using a cooling system according to a preferred embodiment of the invention.

FIG. 2 is a schematic of the cooling system according to a preferred embodiment of the invention operating in a passive mode.

FIG. 3 is a schematic of the cooling system shown in FIG. 3 operating in an active mode.

FIG. 4 is a schematic of an air handling unit of a cooling assembly according to a preferred embodiment of the invention.

FIG. 5 is a schematic of a condensing unit used with the air handling unit shown in FIG. 4.

FIG. 6 elevation view of a cooling system according to a preferred embodiment of the invention.

FIGS. 7A and 7B are examples of server racks cooled by an immersion cooling system used in conjunction with the cooling assembly shown in FIG. 1. FIG. 7A shows a single-phase immersion cooling system, and FIG. 7B shows a two-phase immersion cooling system.

### DETAILED DESCRIPTION OF THE PREFERRED EMBODIMENTS

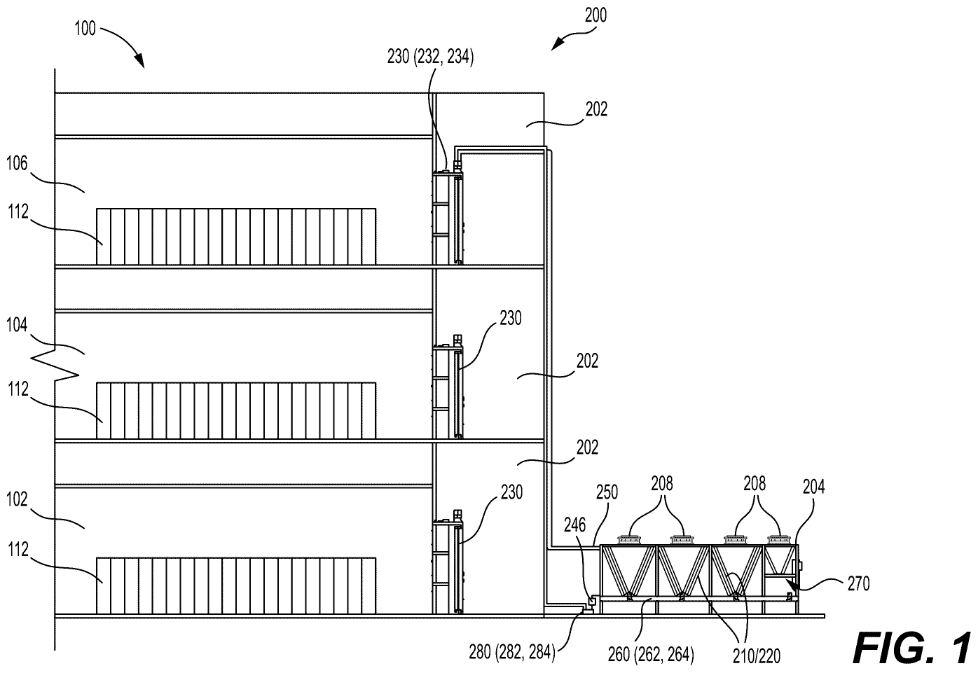

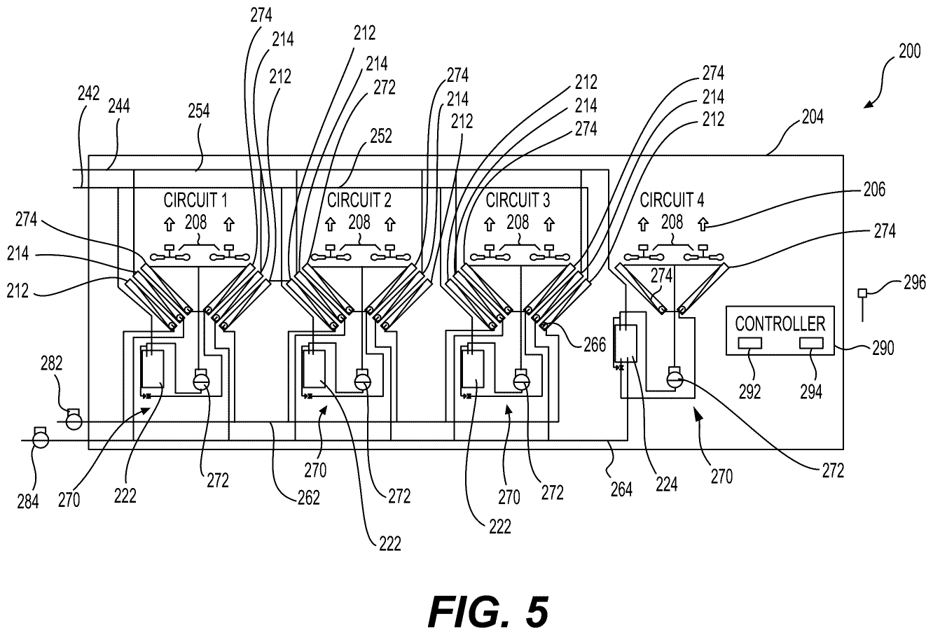

FIG. 1 shows a data center 100 having at least one cooling system 200 according to a preferred embodiment of the invention. Although the cooling system 200 is shown and described in reference to a data center 100, the cooling system 200 is not limited to this application and may be used in other suitable cooling applications, including those used to cool airstreams with air heated from other sources. Electronic components such as servers may be mounted on racks 112. These racks 112 may be arranged in rows forming aisles therebetween. In this arrangement, one aisle is a cold aisle, and another aisle is a hot aisle. Cool, supply air 122 from the cooling system is directed into the cold aisle. The supply air 122 then passes from the cold aisle through the racks and into the hot aisle. As the air passes through the racks 112, the air draws heat from the electronic components, cooling them and resulting in hot air passing into the hot aisle. This air is then directed back to the cooling system 200 as hot, return air 124. Supply air fans 126 (see FIG. 5) are used to draw the return air 124 from the data center 100, pass the return air 124 through the cooling system 200, where it is cooled, and then return the now cooled return air 124 to the data center 100 as supply air 122.

The cooling system 200 may be divided into two sections, an interior air handler 202 and an exterior condensing unit 204. The portion of the cooling system 200 through which the return air 124 flows, is cooled, and is returned as supply air 122 is referred to herein as the interior air handler 202. The data center 100 shown in FIG. 1 is a multi-story data center 100 including a plurality of floors. In this embodiment, the data center 100 has three floors: a first floor 102, a second floor 104, and a third floor 106. The second floor 104 is higher than the first floor 102, and the third floor 106 is higher than both the first floor 102 and the second floor 104. The first floor 102 in this embodiment is a ground floor. Each of the first floor 102, second floor 104, and third floor 106 of this embodiment includes a plurality of racks 112 housing electronic components. At least one interior air handler 202 is positioned on each of the floors 102, 104, 106 to cool the electronic components located in the racks 112 on the corresponding floor.

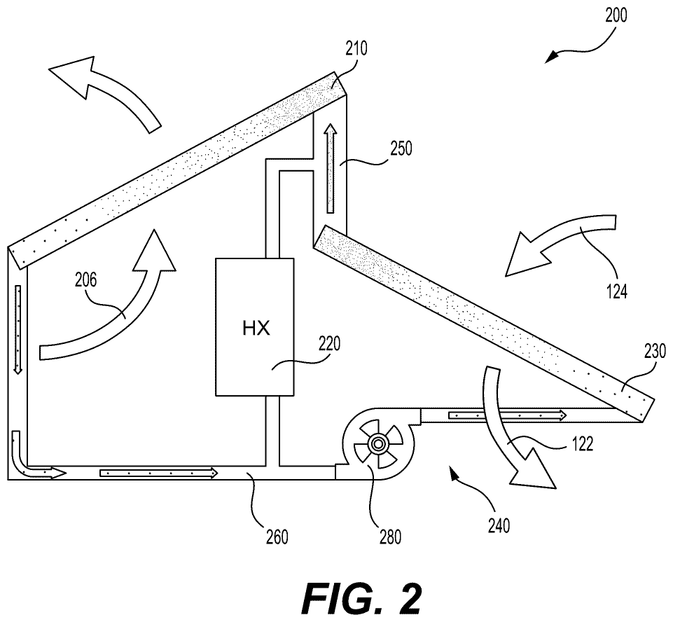

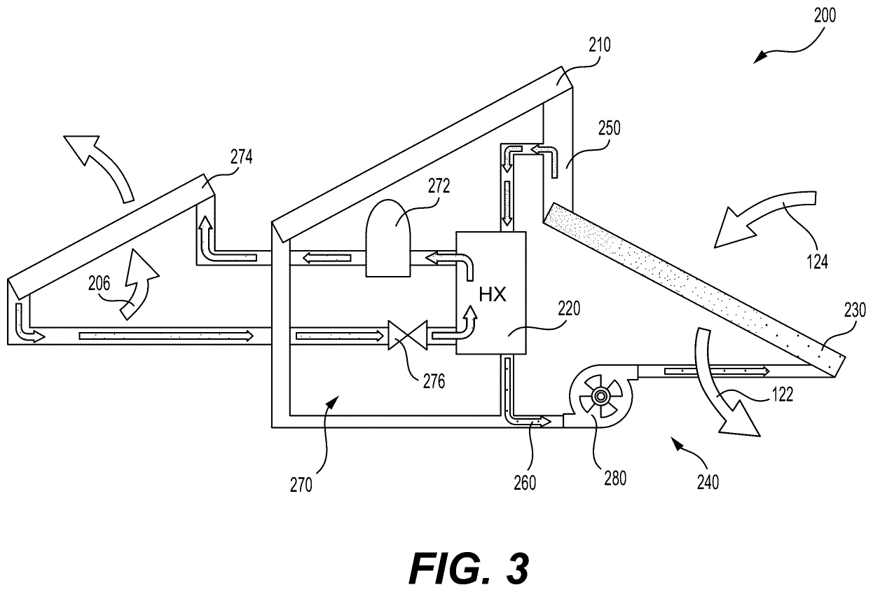

The cooling system 200 of this embodiment has two modes, a passive mode and an active mode. The passive mode may also be referred to as an economization mode. FIG. 2 is a schematic of the cooling system 200 in the passive mode, and FIG. 3 is a schematic of the cooling system 200 in the active mode. The cooling system 200 incorporates the ability to utilize ambient free cooling sinks (passive or economization mode) and to provide active cooling when available ambient free cooling sinks are not at a low enough temperature to provide sufficient heat rejection (active mode). This is accomplished by including two separate condensers 210, 220 operating in parallel. One condenser is referred to herein as a passive condenser 210 and is used in the passive (economization) mode. The other condenser is referred to herein as an active condenser 220 and is used in the active mode.

The cooling system 200 is used to cool a process fluid that contains extracted heat from the electronic components, such as servers, in the racks. The primary coolant loop 240 includes an evaporator 230 thermally coupled to the process fluid. In this embodiment, the process fluid is air, more specifically, the return air 124, and the evaporator 230 is a coil and preferably a one-pass, flooded coil. Any suitable coil may be used including, for example, finned tube coils or microchannel coils, such as those described U.S. Patent Application Pub. Nos. 2018/0038660 and 2021/0368647, the disclosures of which are incorporated by reference herein in their entirety. In both the passive mode and the active mode, the return air 124 is directed over the outer surface of the evaporator 230 by the supply air fans 126. A primary cooling medium is contained within the evaporator 230. The primary cooling medium may be any suitable refrigerant that changes phase from a liquid to a gas, including for example R-134a, and even natural refrigerants such as water. The primary cooling medium also may be referred to as a refrigerant herein. The hot, return air 124 evaporates the primary cooling medium in the evaporator 230 as it passes over the outer surface of the evaporator 230. The phase change of the primary cooling medium from a liquid phase to a gas (or vapor) phase cools the return air 124, allowing it to be returned to the data center 100 as cool, supply air 122.

As noted above and discussed further below, the process fluid may be other suitable fluids including, for example, liquids such as water, water and glycol mixtures, and a non-conductive fluid (dielectric). In these embodiments, the evaporator 230 may be other suitable heat exchangers, including, for example, a plate heat exchanger, a coaxial heat exchanger, or a shell and tube heat exchanger.

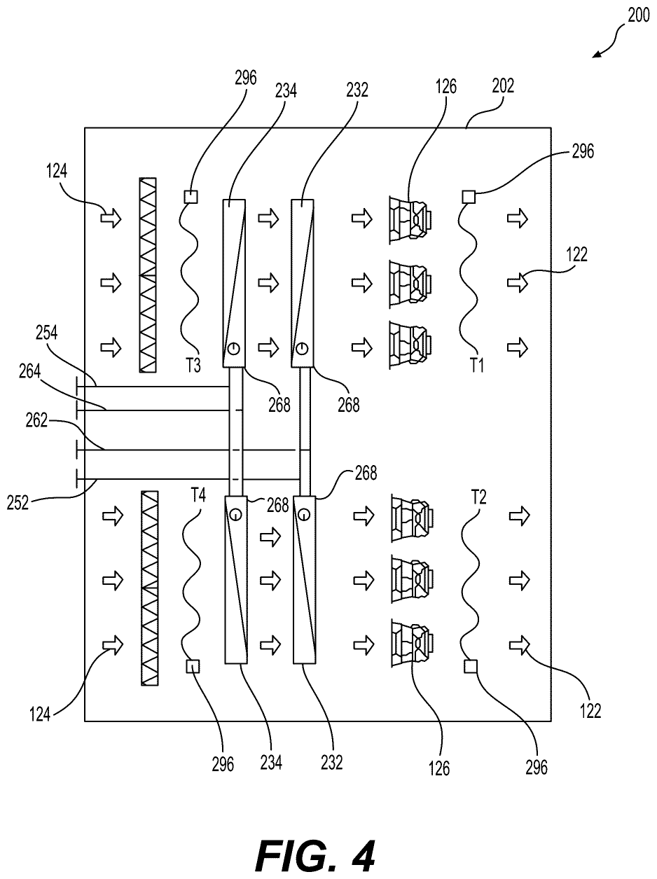

The primary cooling medium circulates through a primary coolant loop 240 including the evaporator 230. The primary coolant loop 240 includes tubes, pipes, conduits, and the like, to fluidly connect the various components of the primary coolant loop 240, some of which are shown in FIGS. 4 and 5. After being heated in the evaporator 230, the primary cooling medium in the gas phase flows through a vapor pipe 250 to one of the two condensers 210, 220.

In the passive mode, shown in FIG. 2, the vapor travels to the passive condenser 210. As with the evaporator 230, the passive condenser 214 of this embodiment is a coil, preferably a one-pass coil, and any suitable coil may be used including, for example, tube coils (both finned and unfinned) or microchannel coils, such as those described in U.S. Patent Application Pub. No. 2018/0038660. Scavenger air 206 is drawn across an outer surface of the passive condenser 210 by scavenger fans 208 (see FIG. 1). In this embodiment, the scavenger air 206 is ambient air drawn from the outdoor environment surrounding the cooling system 200 and, more specifically, the condensing unit 204. As the scavenger air 206 passes over the passive condenser 210, the heat of the primary cooling medium contained in the passive condenser 210 is released to the scavenger air 206, condensing the primary cooling medium. The primary cooling medium changes phase from gas to liquid. The primary cooling medium is then supplied to the evaporator 230 through a liquid refrigerant line 260. The scavenger air 206 is exhausted to the outside by the scavenger fans 208.

When the ambient air conditions are not sufficient to cool the return air 124 to the desired conditions (e.g., temperature) for the supply air 122, the cooling system 200 may be operated in an active mode shown in FIG. 3. In the active mode, the primary cooling medium, in the vapor phase, flows to the active condenser 220 through the vapor pipe 250 and is condensed in an active condenser. The active condenser 220 is configured to have a secondary cooling medium selectively provided thereto. In the active condenser 220, heat is transferred from the primary cooling medium to the secondary cooling medium of a secondary cooling system 270. The secondary cooling medium may be any suitable refrigerant medium, including, for example, cooled (or chilled) water or a vapor change refrigerant used in a direct expansion cooling system. In some embodiments, a mixture of water and glycol is used instead of water alone, and thus a chilled water and glycol mixture may be used as the secondary cooling medium. The active condenser 220 may be any suitable heat exchanger including, for example, a plate heat exchanger, a coaxial heat exchanger, or a shell and tube heat exchanger. Accordingly, the active condenser 220 may also be referred to herein as a heat exchanger (HX). As the heat from the primary cooling medium is rejected to the secondary cooling medium (absorbed by the secondary cooling medium), the primary cooling medium condenses from a vapor to a liquid. As with the passive condenser 210, the primary cooling medium is then supplied to the evaporator 230 through a liquid refrigerant line 260.

In this embodiment, the secondary cooling system 270 is a direct expansion (DX) cooling system using the common refrigeration cycle, and the secondary cooling medium is any suitable refrigerant used in such systems. The secondary cooling system 270 includes a compressor 272 to increase the pressure and temperature of the secondary cooling medium before it is cooled in a condenser 274. In this embodiment, the condenser 274 of the secondary cooling system 270 may also be cooled by the scavenger air 206, and the condenser 274 of the secondary cooling system 270 also may be of any suitable condensers, such as those discussed above for the passive condenser 210. The secondary cooling medium then passes through an expansion valve 276, reducing its pressure and temperature, before flowing into the active condenser 220.

The cooling system 200 preferably operates without the use of valves to switch between modes. In this embodiment, the passive condenser 210 and active condenser 220 are arranged in parallel with each other with respect to the flow of the primary cooling medium. The vapor pipe 250 is bifurcated such that the primary cooling medium in the gas phase flows from the evaporator 230 to one of the passive condenser 210 and the active condenser 220. The primary cooling medium in the gas phase naturally travels to the colder of the two condensers 210, 220 to condense. During the passive mode, the primary cooling medium in the gas phase travels to the passive condenser 210, and, during the active mode, the bulk of the primary cooling medium in the gas phase travels to the active condenser 220. Thus, by activating the secondary cooling system 270 to cool the active condenser 220, the cooling system 200 automatically switches from passive mode to active mode, and by deactivating the secondary cooling system 270, the cooling system 200 switches back to the passive mode. When the ambient temperature is not low enough to provide sufficient heat rejection, the secondary cooling system 270 is activated and at least some of the primary cooling medium in the gas phase switches from being received by the passive condenser 210 to the active condenser 220 without operating any valves located between the evaporator and the passive condenser and between the evaporator and the heat exchanger. In the passive mode, the secondary cooling system 270 is not activated and the secondary cooling medium is not provided to the active condenser 220. In the passive mode, the active condenser 220 does not supply the primary cooling medium in the liquid phase to the evaporator 230. In the active mode, some of the primary cooling medium may condense even in the passive condenser 210.

As noted above, after being condensed in either the passive condenser 210 or the active condenser 220, the primary cooling medium in the liquid phase is supplied to the evaporator 230 through a liquid refrigerant line 260. The passive condenser 210 and the active condenser 220 are both fluidly coupled to a common liquid refrigerant line 260 (also referred to as a liquid line). A pump 280 is located in the liquid refrigerant line 260 and configured to pump the primary cooling medium in the liquid phase to the evaporator. The use of a pump 280 enables the cooling system 200 to be utilized in configurations that are not conducive to the use of natural circulation and gravity, such as conditions where the condensers cannot be placed high enough to provide sufficient pressure head to support the flow of the primary cooling medium in the primary coolant loop 240. Such configurations include, for example, the multi-story data center 100 shown in FIG. 1. The roof of the data center 100 may not have sufficient space and/or strength to support all of the condensing units 204 needed to sufficiently cool the racks 112 of the data center 100. The condensing unit 204, which includes the passive condenser 210 and the active condenser 220, can be placed on the ground, such as along the perimeter of the data center 100, and the pump 280 can then supply the primary cooling medium in the liquid phase to the evaporator 230 located on a floor, such as the second floor 104 or the third floor 106, that is at an elevation higher than the passive condenser 210 and the active condenser 220.

In the embodiment shown in FIGS. 2 and 3, the cooling system 200 includes one of each of the passive condenser 210, the active condenser 220, and the evaporator 230. But in some embodiments, a plurality of each of these components may be used, such as in the cooling system 200 shown in FIGS. 4 and 5. FIGS. 4 and 5 are schematics of a cooling system 200 having a plurality of the passive condensers 210, the active condensers 220, and the evaporators 230. FIG. 4 shows the interior air handler 202 and FIG. 5 shows the condensing unit 204 of the cooling system 200 of this embodiment.

The cooling system 200 may include a plurality of primary coolant loops 240. In this embodiment, the cooling system 200 includes two primary coolant loops 240, a first primary coolant loop 242 and a second primary coolant loop 244. As shown in FIG. 4, each of the first primary coolant loop 242 and the second primary coolant loop 244 includes at least one evaporator 230. In this embodiment, the first primary coolant loop 242 includes two first evaporators 232, and the second primary coolant loop 244 includes two second evaporators 234. The first evaporators 232 are arranged in parallel relative to the return air 124 and are connected to both a first common vapor pipe 252 and first common liquid refrigerant line 262. Likewise, the second evaporators 234 are arranged in parallel relative to the return air 124 and are connected to both a second common vapor pipe 254 and a second common liquid refrigerant line 264. Relative to the return air 124, each first evaporator 232 is arranged in series with one of the second evaporators 234. Return air 124 is directed across the second evaporator 234 before being directed across the first evaporator 232.

The condensing unit 204 shown in FIG. 5 includes four circuits, a first circuit (Circuit 1), a second circuit (Circuit 2), a third circuit (Circuit 3), and a fourth circuit (Circuit 4). Although the condensing unit 204 is described herein as having four circuits, any suitable number of circuits may be used. In addition, although described with specific components in each of these four circuits (for example, passive condensers 210 and active condensers 220), various arrangements and quantities of these components are contemplated to be within the scope of the invention.

As shown in FIG. 5, the first primary coolant loop 242 includes a plurality of first passive condensers 212. In this embodiment, the first primary coolant loop 242 includes six first passive condensers 212. The first passive condensers 212 are connected in parallel with each other and the first evaporators 232 are fluidly connected to each of the first passive condensers 212 by the first common vapor pipe 252 and the first common liquid refrigerant line 262. Two of the first passive condensers 212 are located in each of the first, second, and third circuits.

The first primary coolant loop 242 also includes three first active condensers 222. One of each of the three first active condensers 222 is located in each of of the first, second, and third circuits. In this embodiment, each of the secondary cooling systems 270 includes two condensers 274 connected in parallel to each other. The condensers 274 are located in the same circuit as the corresponding first active condenser 222. Note the compressor 272 is labeled in FIG. 5, but for clarity of the expansion valve 276 is not labeled. The first active condensers 222 are connected in parallel with each other and also in parallel with each of the first passive condensers 212. The first evaporators 232 are also fluidly connected to each of the first active condensers 222 by the first common vapor pipe 252 and the first common liquid refrigerant line 262.

The second primary coolant loop 244 also includes a plurality of second passive condensers 214. In this embodiment, the second primary coolant loop 244 includes six second passive condensers 214. The second passive condensers 214 are connected in parallel with each other, and the second evaporators 234 and are fluidly connected to each of the second passive condensers 214 by the second common vapor pipe 254 and the second common liquid refrigerant line 264. Two of the second passive condensers 214 are located in each of the first, second, and third circuits.

In this emboidment, the second primary coolant loop 244 includes one second active condenser 224 located in parallel with the six second passive condensers 214. The second active condenser 224 is also fluidly connected to the second evaporators 234 by the second common vapor pipe 254 and the second common liquid refrigerant line 264. The second active condenser 224 of the second primary coolant loop 244 is located in the fourth circuit. The fourth circuit includes the second active condenser 224 and its corresponding secondary cooling system 270, but does not include any second passive condensers 214. Each of the four circuits thus includes a secondary cooling system 270.

The arrangements of each of the first, second, and third circuits are similar to each other. The following description of the first circuit applies equally to the second and third circuits. The condensers 212, 214, 222 in the first circuit are arranged in two sets, a first condenser set and a second condenser set. Scavenger air 206 may be driven over the outer surfaces of each of the condenser sets by the scavenger fans 208. The first condenser set and the second condenser set are arranged in parallel with each other relative to the air flow of the scavenger air 206. Each of the first condenser set and the second condenser set contains one of each of the first passive condenser 212 of the first primary coolant loop 242, the second passive condenser 212 of the second primary coolant loop 244, and the condenser 274 of the secondary cooling system 270.

The condensers 212, 212, 274 are arranged in series relative to the air flow of the scavenger air 206. The scavenger air 206 is drawn by scavenger fans 208 of the first circuit through each of the condensers as follows. The scavenger air 206 is ambient air drawn from the outdoor environment surrounding the condensing unit 204 and is first passed through the first passive condenser 212 of the first primary coolant loop 242. Next, the scavenger air 206 is passed through the second passive condenser 212 of the second primary coolant loop 244. Then, the scavenger air 206 passes through the condenser 274 of the secondary cooling system 270 before being exhausted to the outside by the scavenger fans 208. Each of the scavenger fans 208 may be independently variable or at least variable between different circuits. This arrangement of condensers 212, 212, 274 in the first circuit allows for a counter flow design. The primary cooling medium in first primary coolant loop 242 is cooler than the primary cooling medium in the second primary coolant loop 244. Thus, the coldest scavenger air 206 passes through the coldest condenser (the first passive condenser 212) first, and then after being heated by the first passive condensers 212, scavenger air 206 passes through the warmer second passive condenser 214.

The cooling system 200 shown in FIGS. 4 and 5, like the cooling system 200 discussed above with reference to FIGS. 2 and 3, preferably does not use valves in the first primary coolant loop 242 and the second primary coolant loop 244 to switch between the active and passive modes. Instead, by activating the secondary cooling system 270 to cool the first active condensers 222 and/or the second active condenser 224, the primary cooling medium in the gas phase naturally travels to the colder active condenser (the first active condensers 222 and/or the second active condenser 224) to condense, and the cooling system 200, through thermodynamic forces, moves from passive mode to active mode.

When the ambient temperatures are low enough, all of the circuits may be operating in the passive (economization) mode, and the speed of the scavenger fans 208 may be adjusted to help control the temperature of the supply air 122 to a desired set point. If the temperature of the supply air 122 is above the set point and the flow rate of the scavenger air 206 is at its maximum, at least one secondary cooling system 270 may be engaged and the secondary cooling medium supplied to at least one of the first active condensers 222 or second active condenser 224. In the cooling system 200 shown in FIGS. 4 and 5, the secondary cooling system 270 may be staged on by circuits, as necessary, to maintain the temperature of the supply air 122 at the set point. Although the secondary cooling system 270 of the circuits may be staged on in different sequences, one approach is to stage on the secondary cooling systems 270 successively, as needed, in the order of the first circuit, then the second circuit, then the third circuit, and then the fourth circuit. Thus, in this embodiment, the secondary cooling systems 270 of the first primary coolant loop 242 may be staged on before the secondary cooling system 270 of the second primary coolant loop 244. If the temperature of the supply air 122 is below the set point, a secondary cooling system 270 may be deactivated in, for example, the opposite order as the circuits are staged on.

If the temperature of the supply air 122 is below the set point and all secondary cooling systems 270 (active cooling modes) are off with the fan speed of the scavenger fans 208 at a minimum, scavenger fans 208 may be staged off as necessary to maintain the temperature of the supply air 122 at the set point. In a case where all but one of the scavenger fans 208 are off, only one of the first primary coolant loop 242 and the second primary coolant loop 244 may be operated. As discussed below, each of the first primary coolant loop 242 and the second primary coolant loop 244 includes a pump 280, namely a first pump 282 and a second pump 284, respectively, to supply the primary cooling medium in the liquid phase to the first evaporators 232 and the second evaporators 234. Operating only one of the first primary coolant loop 242 or the second primary coolant loop 244 can be achieved by operating only one of the first pump 282 or the second pump 284. When the pump 282, 284 is not operating, the corresponding loop 242, 244 is deactivated.

The first pump 282 and the second pump 284 may also be used to help regulate the cooling system 200. Each of the first pump 282 and the second pump 284 may be configured to precisely control the liquid level (amount of primary cooling medium in the liquid phase) in the first evaporators 232 and second evaporators 234, respectively, and maintain a desired temperature of the vapor leaving each evaporator 232, 234. For example, each of first pump 282 and the second pump 284 may be a variable speed pump and controlling the speed of the pump 282, 284 controls the amount of primary cooling medium supplied to the first evaporators 232 and the second evaporators 234. Using the first pump 282 and the second pump 284 in such a manner allows the primary cooling medium to efficiently circulate through the first primary coolant loop 242 and the second primary coolant loop 244 for a wide range of heat loads and ambient air conditions. Adjusting the speed of the pump 282, 284 can be used to prevent too much liquid 204 from entering the evaporators 232, 234 (e.g., flooding the evaporator 232, 234), which could inhibit vapor flow out of the evaporator 232, 234. Further, adjusting the speed of the pump 282, 284 can be used to prevent too little liquid from entering the evaporators 232, 234 (e.g., starving the evaporator 232, 234), which could inhibit effective and efficient condensing in the condensers 212, 214, 222, 224. Such considerations, and speed control for the pump 282, 284, may be particularly relevant where the interior air handler 202 and the condensing unit 204 are separated, as greater distances require larger amounts of the primary cooling medium, further exacerbating the issues discussed above such as flooding.

Various approaches may be used to set the speed of the pumps 282, 284 and thus the amount of liquid flowing into the evaporators 232, 234. For example, the speed of the pumps 282, 284 may be based on heat absorption in the evaporator 232, 234, heat rejection of the return air 124/supply air 122, heat rejection in the condensers 212, 214, 222, 224, heat absorption by the scavenger air 206, or superheat of the vapor. These factors for controlling the speed of the pumps 282, 284 may be measured as described in U.S. Patent Application Pub. No. 2021/0368647, the disclosure of which is incorporated by reference herein in its entirety.

A controller 290 may be used to operate the cooling system 200. In this embodiment, the controller 290 is a microprocessor-based controller that includes a processor 292 for performing various functions discussed herein and a memory 294 for storing various data. The controller 290 may also be referred to as a CPU. In some embodiments, control of the cooling system 200 may be implemented by way of a series of instructions stored in the memory 294 and executed by the processor 292.

The controller 290 may be communicatively coupled to various temperature sensors (“TS”) 296 to monitor the temperature of various environments. The controller 290 is configured to receive temperature information, such as the temperature, from the temperature sensors 296. As shown in FIG. 4, for example, a temperature sensor 296 is used to monitor the temperature of the supply air 122, allowing the temperature sensor 296 to transmit (and the controller 290 to receive) such as the temperature of the supply air 122. A temperature sensor 296 may also be used to monitor the temperature of the return air 124. Other temperature sensors 296 may be used to monitor other conditions such as temperature sensor 296 positioned to monitor the ambient air temperature (temperature of the scavenger air 206), as shown in FIG. 5. Other temperature sensors 296 and other sensors may be used to measure various parameters of the cooling system 200 and each of the first primary coolant loop 242, second primary coolant loop 244, and secondary cooling systems 270. For example, loop sensors may measure the temperature and pressure of the primary cooling medium in each loop using a temperature sensor and a pressure sensor, respectively.

The controller 290 may also be communicatively and operatively coupled to other components of the cooling system 200 and used to control those components as well. For example, the supply air fans 126 and the scavenger fans 208 may be communicatively and operatively coupled to the controller 290, and thus the controller 290 may be used to operate the supply air fans 126 and the scavenger fans 208 as discussed above. The controller 290 may also be communicatively and operatively coupled to the secondary cooling system 270 of each loop and used to turn on or off (activate or deactivate) the secondary cooling system 270, as discussed above. Further, the controller 290 may be communicatively and operatively coupled to the first pump 282 and the second pump 284 to control the operation of each of the first pump 282 and the second pump 284, as discussed herein.

As noted above, each of the first passive condensers 212 and the first active condensers 222 may supply the primary cooling medium in the liquid phase to the first common liquid refrigerant line 262. Likewise, each of the second passive condensers 214 and the second active condenser 224 may supply the primary cooling medium in the liquid phase to the second common liquid refrigerant line 264. As shown in FIG. 5, the first common liquid refrigerant line 262 includes a first pump 282 and the second common liquid refrigerant line 264 includes a second pump 284. The first pump 282 is positioned downstream of each of the first passive condensers 212 and the first active condensers 222, and the second pump 284 is positioned downstream of the second passive condensers 214 and the second active condenser 224. The first pump 282 and the second pump 284 arc positioned upstream of the first evaporators 232 and the second evaporators 234, respectively. Each of the first pump 282 and the second pump 284 is configured to pump the primary cooling medium in the liquid phase to the first evaporators 232 and the second evaporators 234, respectively.

As noted above and shown in FIG. 1, the condensing unit 204 is positioned lower than the interior air handler 202, and thus the first passive condensers 212, the second passive condensers 214, the first active condensers 222, and the second active condenser 224 are positioned lower than the first evaporators 232 and the second evaporators 234. More specifically, each of the condensers 212, 214, 222, 224 includes an outlet 266 (see FIG. 5) fluidly connected to the first common liquid refrigerant line 262 or second common liquid refrigerant line 264 and configured to supply the primary cooling medium in the liquid phase. Each of the first evaporators 232 and second evaporators 234 also includes an inlet 268 (FIG. 4) fluidly connected to the first common liquid refrigerant line 262 or second common liquid refrigerant line 264. The inlets 268 are fluidly connected to corresponding outlets 266 by the first common liquid refrigerant line 262 or second common liquid refrigerant line 264, and configured to receive the primary cooling medium in the liquid phase. As illustrated in FIG. 1, the inlets 268 are located at an elevation higher than the outlets 266. In this configuration, natural circulation and gravity does not produce sufficient pressure to supply the primary cooling medium in the liquid phase from the condensers 212, 214, 222, 224. The inlets 268 of the first evaporators 232 and the second evaporators 234 are located at an elevation where gravity and natural circulation are not sufficient to move the primary cooling medium from the outlets 266 of the condensers 212, 214, 222, 224 to the inlets 268. Instead, the first pump 282 and the second pump 284 are used to provide the pressure to drive the primary cooling medium in the liquid phase. The use of the first pump 282 and the second pump 284 thus enables additional configurations for the cooling system 200 that are not available when relying on natural circulation and gravity alone.

There may be other configurations where the inlets 268 of the first evaporators 232 and the second evaporators 234 are located at an elevation where gravity and natural circulation are not sufficient to move the primary cooling medium from the outlets 266 of the condensers 212, 214, 222, 224 to the inlets 268. In a configuration that operates without the use of pumps (e.g., first pump 282 and second pump 284), the elevation of the condensers 212, 214, 222, 224 relative to the evaporators 232, 234 and, more specifically, the difference in elevation between the outlets 266 and the inlets 268, provides the maximum hydraulic force available to drive the primary cooling medium in the liquid phase to the evaporators 232, 234. This hydraulic force must be sufficient to overcome the resistance (pressure drop) to the flow of the primary cooling medium within the primary coolant loop 240 (e.g., each of the first primary coolant loop 242 and the second primary coolant loop 244) in order to circulate the primary cooling medium within the primary coolant loop 240 by natural circulation and gravity. Where the available pressure (hydraulic force) due to elevation is less than the pressure drop of the system (primary coolant loop 240), the system will not operate by natural circulation and gravity and options available in such situations include increasing pipe sizing or reducing the massflow of the system. Increasing the pipe sizing, however, increases the installation cost and increases the refrigerant charge required, and reducing the massflow reduces the heat rejection capability of the system. In such situations, the embodiments using a pump 280 discussed herein may be preferred.

The following tables illustrate examples of the second primary coolant loop 244 showing elevations where the embodiments discussed herein may be preferred. Table 1 shows the pressure drop of the system in equivalent linear feet (meters) of pipe for two different mass flows: a mass flow that provides 400 kW of heat rejection capacity and a mass flow that provides 300 kW of heat rejection capacity. A straight length of pipe has a pressure drop per lineal foot of pipe, and the other components in the system, such as elbows, t-sections, the condensing coils, the evaporator coils, etc., may also be converted into equivalent linear feet (meters) of pipe (see, e.g., table 14.7 of the Copper Development Association Inc., Design Handbook). The total is then added to arrive at the total equivalent linear feet (meters) for the second primary coolant loop 244 shown in Table 1. The following examples use R-134a as the primary cooling medium. The diameter of the second common vapor pipe 254 is four inches (10 cm), and the diameter of the second common liquid refrigerant line 264 is two inches (5 cm). Table 2 shows the available hydraulic force for different elevation differences.

TABLE 1

| Equivalent Linear | Pressure Drop (PSI (kPa)) | |
|---|---|---|
| Feet (Meters) | 400 kW Heat Rejection | 300 kW Heat Rejection |
| 50 (15) | 3.1 (21.3) | 2.7 (18.6) |
| 75 (23) | 3.3 (22.8) | 2.8 (19.3) |
| 100 (30) | 3.5 (24.1) | 2.9 (20.0) |
| 125 (38) | 3.6 (24.8) | 3.0 (20.7) |
| 150 (46) | 3.7 (25.5) | 3.1 (21.3) |
| 175 (53) | 3.9 (26.9) | 3.2 (22.1) |
| 200 (61) | 4.0 (27.6) | 3.3 (22.8) |
| 225 (69) | 4.2 (29.0) | 3.3 (22.8) |
| 250 (76) | 4.3 (29.6) | 3.4 (23.4) |
| 275 (84) | 4.5 (31.0) | 3.5 (24.1) |
| 300 (91) | 4.6 (31.7) | 3.6 (24.8) |

TABLE 2

| Vertical | Available Hydraulic |
|---|---|
| Separation (Feet) | Force (PSI (KPa) |
| 4 (1.2) | 3.1 (21.4) |
| 6 (1.8) | 4.2 (29.0) |
| 8 (2.4) | 5.2 (35.9) |
| 10 (3.0) | 6.2 (42.7) |

As can be seen by comparing the available hydraulic force (Table 2) to the pressure drop (Table 3), a vertical separation of eight feet (2.4 m) or ten feet (3.0 m) provides sufficient pressure for the system (second primary coolant loop 244) to operate by natural circulation and gravity for systems having equivalent linear feet of even 300 feet (91 m). Likewise, a vertical separation of six feet (1.8 m) provides sufficient pressure for the system (second primary coolant loop 244) to operate by natural circulation and gravity for systems having equivalent linear feet of even 300 feet (91 m) with a mass flow for 300 kW in heat rejection. In contrast, the embodiments discussed herein may be used where the available hydraulic force is not sufficient. As can be seen from Tables 1 and 2 above, in a 300 kW heat rejection system, the embodiments discussed herein may be used when the vertical separation is four feet (1.2 m) and the primary coolant loop 240 has a pressure drop of 150 equivalent linear feet (46 m) or more. Similarly, in a 400 kW heat rejection system, the embodiments discussed herein may be used when the vertical separation is six feet (1.8 m) and the primary coolant loop 240 has a pressure drop for 225 equivalent linear feet (69 m) or more and, more preferably when a factor of safety (0.5 PSI (3.4 kPa)) is applied, 150 equivalent linear feet (46 m) or more. In some cases, particularly with the application of a (0.5 PSI (3.4 kPa)) factor of safety, the embodiments discussed herein may be used when the vertical separation is four feet (1.2 m) or less regardless of the equivalent linear feet.

Moreover, relying on natural circulation and gravity, if the condensers 212, 214, 222, 224 and evaporators 232, 234 are positioned appropriately, the system may use relatively large first common liquid refrigerant line 262 and second common liquid refrigerant line 264 to reduce the pressure drop of the first common liquid refrigerant line 262 and second common liquid refrigerant line 264, thus resulting in a relatively large amount of primary cooling medium in each of the first primary coolant loop 242 and the second primary coolant loop 244. Without pumps 280, the line size may be about two 2⅛ inches (5.40 cm), but with a pump 280, the line size can be reduced to about 1⅜ inches (3.49 cm). With corresponding reductions in the first common liquid refrigerant line 262 and second common liquid refrigerant line 264, the refrigerant charge of the primary cooling medium may be reduced by up to forty percent depending on interconnecting line length. The interconnecting line is the portions of the vapor pipes 252, 254 and liquid refrigerant lines 262, 264 between the interior air handler 202 and the condensing unit 204.

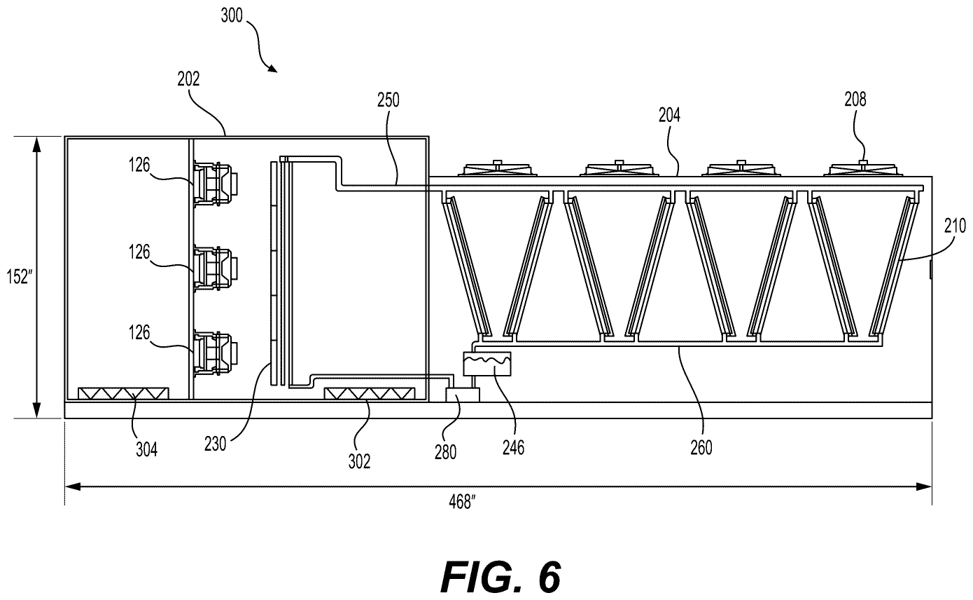

Another benefit of using pumps, such as pump 280, is that the pumped system facilitates combining the interior air handler 202 and the condensing unit 204 into a single unit that can be sized to be for shipping over the road. FIG. 6 shows a cooling system 300 that is combined into a single unit and sized for over the road transport. The cooling system 300 may be configured and operated similarly to the cooling system 200 discussed above. Like reference numerals in FIG. 6 refer to the same or similar components as the cooling system 200 discussed above and a detailed description of those components is omitted here. In addition, for simplicity, some components, such as the secondary cooling system 270 are omitted here, but the cooling system 300 may have each of the components discussed above. The use of pump 280 allows the passive condensers 210 to be located at a similar level as the evaporator 230 without an elevation difference that would be required if natural circulation and gravity were driving the flow of the primary cooling medium through the primary coolant loop 240. Thus, the overall height can be reduced to heights acceptable for transport over the road, such as 152 inches (386 cm), for example. Accordingly, the evaporator 230 and the passive condensers 210 may positioned relative to each other such that the overall height of the single unit is 14 feet (4.27 m) or less, such as 13.5 feet (4.11 m) or less, or 13 feet (3.96 m) or less. In these embodiments the active condensers 220 may also be positioned relative to the evaporator 230 and the passive condensers 210 to allow for the overall height to a height acceptable for transport over the road.

Over the road transport of a single unit system (cooling system 300) may be advantageous as it allows the unit to be factory built as a single unit and reduces the assembly required at the site where the cooling system 300 will be used. The cooling system 300 can thus be charged and tested for faster deployment and improved quality control. This system may then be connected to the racks 112 to be cooled by a suitable fluid conduit, such as air ducts (not shown) to the rooms holding the racks 112, in this embodiment. The cooling system 300 thus includes a process fluid inlet and a process fluid outlet. Each of the process fluid inlet and a process fluid outlet are fluidly connected to the evaporator 230 to provide the process fluid to and receive the cooled process fluid from the evaporator 230. In this embodiment, the cooling system 300 includes supply air opening 302 and a return air opening 304, that can be connected to ducts to convey the supply air 122 and the return air 124, respectively.

The single unit system (cooling system 300) has additional benefits, including, for example, a reduced primary cooling medium (refrigerant) charge because the amount of piping can be reduced by, for example, omitting the interconnecting piping. The single unit system (cooling system 300) may provide for additional flexibility in the data center 100 configuration as different duct configurations may more radically adapt to the layout and configuration of the data center 100 as compared to pipes such as the vapor pipe 250 and liquid refrigerant line 260, discussed above. Moreover, moving the interior air handler 202 to a position that is exterior to the data center 100 allows for additional floor space on each of the floors 102, 104, 106, that can be used for various purposes including allowing additional racks 112.

In some embodiments, the primary coolant loop 240 (e.g., each of the first primary coolant loop 242 and the second primary coolant loop 244) may include a refrigerant receiver 246, as shown in FIGS. 1 and 6. The refrigerant receiver 246 is fluidly connected to each of the first common liquid refrigerant line 262 and the second common liquid refrigerant line 264 downstream of the outlets 266 of the condensers 212, 214, 222, 224 and upstream of the first pump 282 or the second pump 284, respectively. Preferably the refrigerant receiver 246 is located at an elevation that is vertically lower than the bottom of the active condenser(s) 222, 224 so that the primary cooling medium in the liquid phase naturally flows to the refrigerant receiver 246.

The refrigerant receiver 246 may be used when the primary coolant loop 240 is operating in the active mode. Each of the first passive condensers 212 and second passive condensers 214 may have significantly more volume than each of the first active condensers 222 and the second active condenser 224. When operating in the active mode, excess primary cooling medium may be present because of the reduced volume of the first active condensers 222 and the second active condenser 224. The refrigerant receiver 246 may be used to accumulate this excess primary cooling medium and to prevent the primary cooling medium from backing-up into the first active condensers 222 or the second active condenser 224. Such a back-up could reduce the efficiency of the heat rejection in the first active condensers 222 or second active condenser 224. In some embodiments, the refrigerant receiver 246 thus may be used to collect the excess primary cooling medium when the primary coolant loop 240 (e.g., each of the first primary coolant loop 242 and the second primary coolant loop 244) is operating with at least one of the circuits in the active mode. The refrigerant receiver 246 is configured to receive excess primary cooling medium when the evaporator 230 is receiving the primary cooling medium in the liquid phase from at least one of the first active condensers 222 or the second active condenser 224.

The refrigerant receiver 246 may be any suitable refrigerant receiver. Additionally or alternatively, the refrigerant receiver 246 may be an oversized pipe (such as an oversized portion of the first common liquid refrigerant line 262 or second common liquid refrigerant line 264) that is sized appropriately to hold the excess primary cooling medium.

The process fluid cooled by the cooling system 200 in the example discussed above is air (e.g., return air 124). In these previous discussions, air (process fluid) is directed over racks 112 containing electronics and heated before being directed over an evaporator 230 (return air 124) to be cooled. The cooling systems 200 described herein are not limited to cooling air, however, and may be used to cool any suitable fluid. The process fluid may include, for example, liquids such as water, water and glycol mixtures, and a non-conductive fluid (dielectric). In the embodiments discussed above, where the process fluid is air, the evaporator 230 was suitably a microchannel coil or finned tube coils. Where the process fluid is a liquid instead of a vapor (gas), other suitable evaporators 230 may be used, including, for example, a microchannel cold plate, a plate heat exchanger, a coaxial heat exchanger, or a shell and tube heat exchanger.

When the process fluid is a liquid, for example, the process fluid may be circulated in a process fluid loop by a pump. The process fluid may be configured to receive heat from a heat load such as the electronic equipment stored in the rack 112. In some embodiments, the process fluid loop may include an air to liquid heat exchanger and heated air (such as the air in the rack 112) is passed through the heat exchanger to heat the process fluid.

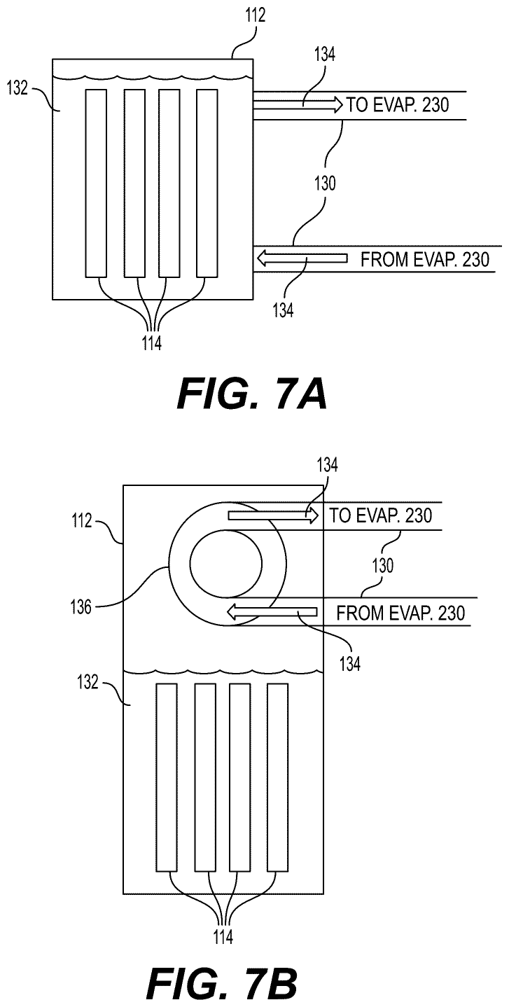

In other embodiments, the cooling system 200 may be used with an immersion cooling system. FIGS. 7A and 7B show examples of a rack 112 used in an immersion cooling system. In FIG. 7A, the servers 114 are submerged in a dielectric 132. The servers 114 heat the dielectric 132, but the dielectric 132 remains a liquid (single phase). The heated dielectric 132 is circulated as the process fluid 134 through the process fluid loop 130 to be cooled and returned to the rack 112 to further cool the servers 114.

In FIG. 7B, the servers 114 are also submerged in the dielectric 132. In this case, the dielectric 132 cools the servers 114 by two-phase cooling. The servers 114 heat the dielectric 132, and the dielectric 132 changes phase into a vapor (gas). The dielectric vapor rises to the top of the rack 112. The top of the rack 112 includes a coil 136. An appropriate process fluid 134 passes through the coil 136 and condenses the dielectric 132. In another embodiment, the dielectric 132 in the vapor phase may be directly cooled by the evaporator 230 as the process fluid 134 instead of using another fluid.

In the embodiments described above, the servers 114 are physically separated from the evaporator 230 and the process fluid loop 130 is used to transport heat from the servers 114 or other information technology (“IT”) equipment to the evaporator 230. The inventions described herein are not so limited, however, and the evaporators 230 may be any liquid to refrigerant heat exchanger, where a circulating liquid (dielectric fluid, water, or other fluid) transports heat from the IT equipment to the refrigerant that is integral to the two-phase thermosiphon loop. Such other suitable evaporators 230 include, for example, a cold plate integrated into the servers 114 or IT component to directly absorb heat from the component and/or chips therein or a plurality of tubular surfaces directly integrated into a submersion cooling system.

Although this invention has been described with respect to certain specific exemplary embodiments, many additional modifications and variations will be apparent to those skilled in the art in light of this disclosure. It is, therefore, to be understood that this invention may be practiced otherwise than as specifically described. Thus, the exemplary embodiments of the invention should be considered in all respects to be illustrative and not restrictive, and the scope of the invention to be determined by any claims supportable by this application and the equivalents thereof, rather than by the foregoing description.

What is claimed is:

1. A cooling system comprising:
an evaporator containing a primary cooling medium, the evaporator being configured to receive a process fluid and, when receiving the process fluid, extract heat from the process fluid to cool the process fluid and to change the phase of the primary cooling medium from liquid to gas;
a passive condenser having an outer surface and being fluidly coupled to the evaporator, the passive condenser being configured to have an airstream directed over the outer surface thereof, and, when the airstream is directed over the outer surface of the passive condenser, the passive condenser is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator;
a heat exchanger fluidly coupled to the evaporator and configured to have a secondary cooling medium selectively provided thereto such that:
(a) when the secondary cooling medium is provided to the heat exchanger, at least some of the primary cooling medium in the gas phase switches from being received by the passive condenser to the heat exchanger without operating any valves located between the evaporator and the passive condenser and between the evaporator and the heat exchanger and the heat exchanger is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator; and
(b) when the secondary cooling medium is not provided to the heat exchanger, the heat exchanger does not supply the primary cooling medium in the liquid phase to the evaporator;
a liquid line fluidly connecting the evaporator to each of the passive condenser and the heat exchanger to supply the primary cooling medium in the liquid phase to the evaporator from at least one of the passive condenser and the heat exchanger; and
a pump located in the liquid line and configured to pump the primary cooling medium in the liquid phase to the evaporator, wherein the passive condenser is arranged in parallel with the heat exchanger relative to the fluid flow of the primary cooling medium.

2. The cooling system according to claim 1, wherein the process fluid is air.

3. The cooling system according to claim 1, wherein the process fluid is a liquid.

4. An electronics system comprising:
at least one electronics component cooled by a dielectric; and
the cooling system according to claim 1, wherein the cooling system cools the dielectric.

5. The electronics system according to claim 4, wherein the process fluid is the dielectric.

6. The cooling system according to claim 1, wherein the secondary cooling medium is a refrigerant of a direct expansion cooling system, the direct expansion cooling system including a compressor and an expansion valve.

7. The cooling system according to claim 1, wherein the secondary cooling medium is chilled water or a chilled water and glycol mixture.

8. The cooling system according to claim 1, wherein, when the secondary cooling medium is provided to the heat exchanger, some of the primary cooling medium is received by both the passive condenser and the heat exchanger (i) to transfer heat from the primary cooling medium, (ii) to change the phase of the primary cooling medium from gas to liquid, and (iii) to supply the primary cooling medium in the liquid phase to the evaporator.

9. The cooling system according to claim 1, further comprising a refrigerant receiver configured to accumulate excess primary cooling medium, the refrigerant receiver being located in the liquid line upstream of the pump and downstream of the heat exchanger.

10. The cooling system according to claim 9, wherein the refrigerant receiver is located at an elevation that is vertically lower than the bottom of the heat exchanger.

11. The cooling system according to claim 1, wherein the evaporator includes an inlet configured to receive the primary cooling medium in the liquid phase,
wherein the passive condenser includes an outlet configured to supply the primary cooling medium in the liquid phase,
wherein the inlet of the evaporator is fluidly connected to the outlet of the passive condenser by the liquid line, and
wherein the inlet of the evaporator is located at an elevation where gravity and natural circulation are not sufficient to move the primary cooling medium from the outlet of the passive condenser to the inlet of the evaporator.

12. The cooling system according to claim 1, wherein the evaporator includes an inlet configured to receive the primary cooling medium in the liquid phase,
wherein the heat exchanger includes an outlet configured to supply the primary cooling medium in the liquid phase,
wherein the inlet of the evaporator is fluidly connected to the outlet of the heat exchanger by the liquid line, and
wherein the inlet of the evaporator is located at an elevation where gravity and natural circulation are not sufficient to move the primary cooling medium from the outlet of the heat exchanger to the inlet of the evaporator.

13. The cooling system according to claim 1, wherein the evaporator includes an inlet configured to receive the primary cooling medium in the liquid phase,
wherein the passive condenser includes an outlet configured to supply the primary cooling medium in the liquid phase,
wherein the inlet of the evaporator is fluidly connected to the outlet of the passive condenser by the liquid line, and
wherein the inlet of the evaporator is located at an elevation higher than the outlet of the passive condenser.

14. The cooling system according to claim 1, wherein the evaporator includes an inlet configured to receive the primary cooling medium in the liquid phase,
wherein the heat exchanger includes an outlet configured to supply the primary cooling medium in the liquid phase,
wherein the inlet of the evaporator is fluidly connected to the outlet of the heat exchanger by the liquid line, and
wherein the inlet of the evaporator is located at an elevation higher than the outlet of the heat exchanger.

15. The cooling system according to claim 1, wherein the evaporator includes an inlet configured to receive the primary cooling medium in the liquid phase,
wherein the passive condenser includes an outlet configured to supply the primary cooling medium in the liquid phase,
wherein the inlet of the evaporator is fluidly connected to the outlet of the passive condenser by the liquid line, and
wherein the outlet of the passive condenser is located at an elevation higher than the inlet of the evaporator by a distance of six feet (1.8 m) or less.

16. The cooling system according to claim 15, further comprising a vapor line fluidly connecting the evaporator to each of the passive condenser and the heat exchanger to supply the primary cooling medium in the gas phase from the evaporator to at least one of the passive condenser and the heat exchanger, and
wherein the evaporator, the passive condenser, the heat exchanger, the liquid line, and the vapor line have an equivalent linear feet (meters) that is 225 equivalent linear feet (69 m) or more.

17. The cooling system according to claim 16, wherein the equivalent linear feet (meters) of the evaporator, the passive condenser, the heat exchanger, the liquid line, and the vapor line is 150 equivalent linear feet (46 m) or more.

18. The cooling system according to claim 1, wherein the evaporator includes an inlet configured to receive the primary cooling medium in the liquid phase,
wherein the heat exchanger includes an outlet configured to supply the primary cooling medium in the liquid phase,
wherein the inlet of the evaporator is fluidly connected to the outlet of the heat exchanger by the liquid line, and
wherein the outlet of the heat exchanger is located at an elevation higher than the inlet of the evaporator by a distance of six feet (1.8 m) or less.

19. The cooling system according to claim 18, further comprising a vapor line fluidly connecting the evaporator to each of the passive condenser and the heat exchanger to supply the primary cooling medium in the gas phase from the evaporator to at least one of the passive condenser and the heat exchanger, and
wherein the evaporator, the passive condenser, the heat exchanger, the liquid line, and the vapor line have an equivalent linear feet (meters) that is 225 equivalent linear feet (69 m) or more.

20. The cooling system according to claim 19, wherein the equivalent linear feet (meters) of the evaporator, the passive condenser, the heat exchanger, the liquid line, and the vapor line is 150 equivalent linear feet (46 m) or more.

21. The cooling system according to claim 1, wherein the evaporator is positioned at a level higher than at least one of the passive condenser and the heat exchanger.

22. The cooling system according to claim 1, wherein the pump is a variable speed pump.

23. The cooling system according to claim 22, further comprising a controller operatively coupled to the pump to control the speed of the pump.

24. The cooling system according to claim 23, further comprising a temperature sensor, the controller being communicatively coupled to the temperature sensor to receive temperature information, the controller being configured to control the speed of the pump based on the temperature information.

25. The cooling system according to claim 1, wherein the evaporator, the passive condenser, the heat exchanger, and the pump are integrated into a single unit.

26. The cooling system according to claim 25, wherein the evaporator and the passive condenser are positioned relative to each other such that the overall height of the single unit is 14 feet (4.27 m) or less.

27. The cooling system according to claim 25, further comprising a process fluid inlet fluidly connected to the evaporator and a process fluid outlet fluidly connected to the evaporator.

28. The cooling system according to claim 25, wherein the process fluid inlet is a return air opening capable of being connected to a return air duct and a process fluid outlet is a supply air opening capable of being connected to a supply air duct.

29. A multi-level data center, comprising:
a plurality of floors including a first floor and a second floor, the second floor being higher than the first floor;
a plurality of racks holding electronic components positioned on the second floor; and
the cooling system according to claim 28, wherein the return air opening is connected to the return air duct to receive air from the plurality of racks positioned on the second floor and the supply air opening is connected to the supply air duct to supply air to the plurality of racks positioned on the second floor.

30. A multi-level data center, comprising:
a plurality of floors including a first floor and a second floor, the second floor being higher than the first floor;
a plurality of racks holding electronic components positioned on the second floor; and
the cooling system according to claim 1, wherein the evaporator is positioned on the second floor and the passive condenser and the heat exchanger are positioned lower than the second floor.

31. A cooling system comprising:
an evaporator containing a primary cooling medium, the evaporator being configured to receive a process fluid and, when receiving the process fluid, extract heat from the process fluid to cool the process fluid and to change the phase of the primary cooling medium from liquid to gas;
a plurality of passive condensers, each passive condenser having an outer surface and being fluidly coupled to the evaporator, each the passive condenser being configured to have an airstream directed over the outer surface thereof, and, when the airstream is directed over the outer surface of the passive condenser, the passive condenser is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator;
at least one heat exchanger fluidly coupled to the evaporator and configured to have a secondary cooling medium selectively provided thereto such that:
(a) when the secondary cooling medium is provided to the at least one heat exchanger, at least some of the primary cooling medium in the gas phase switches from being received by the passive condenser to the at least one heat exchanger without operating any valves located between the evaporator and the passive condenser and between the evaporator and the heat exchanger and the at least one heat exchanger is configured (i) to receive the primary cooling medium in the gas phase from the evaporator, (ii) to transfer heat from the primary cooling medium, (iii) to change the phase of the primary cooling medium from gas to liquid, and (iv) to supply the primary cooling medium in the liquid phase to the evaporator; and
(b) when the secondary cooling medium is not provided to the at least one heat exchanger, the heat exchanger does not supply the primary cooling medium in the liquid phase to the evaporator;
a liquid line fluidly connecting the evaporator to each passive condenser of the plurality of passive condensers and the at least one heat exchanger to supply the primary cooling medium in the liquid phase to the evaporator from at least one of the plurality of passive condensers and the at least one heat exchanger; and
a pump located in the liquid line and configured to pump the primary cooling medium in the liquid phase to the evaporator, wherein at least one passive condenser of the plurality of passive condensers is arranged in parallel with the at least one heat exchanger relative to the fluid flow of the primary cooling medium.

32. The cooling system according to claim 31, wherein the passive condensers of the plurality of passive condensers are arranged in parallel with each other relative to the fluid flow of the primary cooling medium.

33. The cooling system according to claim 31, wherein the evaporator includes an inlet configured to receive the primary cooling medium in the liquid phase,
wherein each passive condenser of the plurality of passive condensers includes an outlet configured to supply the primary cooling medium in the liquid phase,
wherein the inlet of the evaporator is fluidly connected to the outlet of each passive condenser of the plurality of passive condensers by the liquid line, and
wherein the inlet of the evaporator is located at an elevation higher than the outlet of each passive condenser of the plurality of passive condensers.

34. The cooling system according to claim 31, wherein the evaporator includes an inlet configured to receive the primary cooling medium in the liquid phase,
wherein the at least one heat exchanger includes an outlet configured to supply the primary cooling medium in the liquid phase,
wherein the inlet of the evaporator is fluidly connected to the outlet of the at least one heat exchanger by the liquid line, and
wherein the inlet of the evaporator is located at an elevation higher than the outlet of the at least one heat exchanger.

35. The cooling system according to claim 31, wherein the secondary cooling medium is a refrigerant of a direct expansion cooling system, the direct expansion cooling system including a compressor and an expansion valve.

36. The cooling system according to claim 31, wherein, when the secondary cooling medium is provided to the at least one heat exchanger, some of the primary cooling medium is received by each of the passive condensers of the plurality of passive condensers and the at least one heat exchanger (i) to transfer heat from the primary cooling medium, (ii) to change the phase of the primary cooling medium from gas to liquid, and (iii) to supply the primary cooling medium in the liquid phase to the evaporator.

37. The cooling system according to claim 31, further comprising a plurality of heat exchangers, each heat exchanger of the plurality of heat exchangers being arranged in parallel with each passive condenser of the plurality of passive condensers relative to the fluid flow of the primary cooling medium.

38. The cooling system according to claim 37, wherein the evaporator includes an inlet configured to receive the primary cooling medium in the liquid phase,
wherein each heat exchanger of the plurality of heat exchangers includes an outlet configured to supply the primary cooling medium in the liquid phase,
wherein the inlet of the evaporator is fluidly connected to the outlet of each heat exchanger of the plurality of heat exchangers by the liquid line, and
wherein the inlet of the evaporator is located at an elevation higher than the outlet of each heat exchanger of the plurality of heat exchangers.
